(19) United States
(12) Patent Application Publication
(10) Pub. No.: US 2017/0082668 A1
(43) Pub. Date: Mar. 23, 2017

(54) MEASURING APPARATUS, MEASURING METHOD, AND RECORDING MEDIUM

(71) Applicant: ADVANTEST CORPORATION, Tokyo (JP)

(72) Inventors: Tsuyoshi ATAKA, Miyagi (JP); Masaichi HASHIMOTO, Miyagi (JP)

(73) Assignee: ADVANTEST CORPORATION, Tokyo (JP)

(21) Appl. No.: 15/231,997

(22) Filed: Aug. 9, 2016

(30) Foreign Application Priority Data
Sep. 17, 2015 (JP) 2015-183719

(51) Int. Cl. G01R 23/02

(52) U.S. Cl. CPC G01R 23/02

(57) ABSTRACT

A measuring apparatus according to the present invention includes a response signal measuring section, an input frequency domain conversion section, a response frequency domain conversion section, and a frequency characteristic acquisition section. The response signal measuring section measures a response signal within a time domain, the response signal being acquired by applying a pulse having a width of not less than one femtosecond nor more than 1000 femtoseconds to an object to be measured. The input frequency domain conversion section converts the pulse into a frequency domain. The response frequency domain conversion section converts a measurement result from the response signal measuring section into a frequency domain. The frequency characteristic acquisition section acquires a frequency characteristic of the object to be measured, from a conversion result provided from the input frequency domain conversion section and a conversion result provided from the response frequency domain conversion section.

### FIELD OF THE INVENTION

The present invention relates to measurement of frequency characteristics of an object to be measured over a wide frequency band.

### BACKGROUND OF THE INVENTION

Conventionally, waveguides are known to be used when measuring scattering parameters (S parameters) of an object to be measured.

### PRIOR ART DOCUMENTS

### Patent Document 1

Japanese Laid-Open Patent Publication [Kokai] No. Hei7-58166

### Patent Document 2

Japanese Translation of PCT International Application No. 2014-506672

### Patent Document 3

Japanese Laid-Open Patent Publication [Kokai] No. Hei7-151837

### SUMMARY OF THE INVENTION

However, waveguides are designed to operate at frequencies in a narrow frequency band, making it difficult to measure frequency characteristics over a wide frequency band.

To measure the frequency characteristics over the frequency band ranging from 110 to 1100 GHz by using waveguides, for example, it is necessary to use many types of waveguides (e.g., six types of waveguides transmitting input signals with frequency bands of 110 to 170 GHz, 140 to 220 GHz, 220 to 325 GHz, 325 to 500 GHz, 500 to 750 GHz, and 750 to 1100 GHz [WR1.0]) while replacing one of the waveguides with another. This process may make the measurement difficult.

Therefore, an object of the present invention is to facilitate the measurement of the frequency characteristics of an object to be measured over a wide frequency band.

According to the present invention, a measuring apparatus includes: a response signal measuring section that measures a response signal within a time domain, the response signal being acquired by applying a pulse having a width of not less than one femtosecond nor more than 1000 femtoseconds to an object to be measured; an input frequency domain conversion section that converts the pulse into a frequency domain; a response frequency domain conversion section that converts a measurement result from the response signal measuring section into a frequency domain; and a frequency characteristic acquisition section that acquires a frequency characteristic of the object to be measured, from a conversion result provided from the input frequency domain conversion section and a conversion result provided from the response frequency domain conversion section.

According to the thus constructed measuring apparatus, a response signal measuring section measures a response signal within a time domain, the response signal being acquired by applying a pulse having a width of not less than one femtosecond nor more than 1000 femtoseconds to an object to be measured. An input frequency domain conversion section converts the pulse into a frequency domain. A response frequency domain conversion section converts a measurement result from the response signal measuring section into a frequency domain. A frequency characteristic acquisition section acquires a frequency characteristic of the object to be measured, from a conversion result provided from the input frequency domain conversion section and a conversion result provided from the response frequency domain conversion section.

The measuring apparatus according to the present invention, may further include: a probe tip that makes contact with the object to be measured; a transmission line connected to the probe tip, the transmission line being adapted to transmit the pulse and the response signal therethrough; a pulse signal source that generates the pulse; and a response signal detector that detects the response signal, wherein the response signal measuring section may measure the response signal within the time domain based on a detection result from the response signal detector.

According to the present invention, no bias voltage may be applied to the transmission line, and the transmission line may be connected directly to both the pulse signal source and the response signal detector.

According to the present invention, bias voltage may be applied to the transmission line, and the transmission line may be electromagnetically coupled to both the pulse signal source and the response signal detector.

The measuring apparatus according to the present invention, may further include: an incident signal source that allows a weak, low-frequency signal in the pulse to enter the object to be measured; an incident signal measuring section that measures an incident signal entered by the incident signal source; an acquired signal measuring section that measures an acquired signal obtained by allowing the incident signal to enter the object to be measured; and a frequency characteristic measuring section that measures a frequency characteristic of the object to be measured, from measurement results provided from the incident signal measuring section and the acquired signal measuring section.

The measuring apparatus according to the present invention, may further include: a time difference measuring section that measures a time difference between the pulse and the response signal, wherein the response signal measuring section may measure the response signal within the time domain after a time based on the time difference has passed since generation of the pulse.

The present invention is a measuring method including: a response signal measuring step that measures a response signal within a time domain, the response signal being acquired by applying a pulse having a width of not less than one femtosecond nor more than 1000 femtoseconds to an object to be measured; an input frequency domain conversion step that converts the pulse into a frequency domain; a response frequency domain conversion step that converts a measurement result from the response signal measuring step into a frequency domain; and a frequency characteristic acquisition step that acquires a frequency characteristic of the object to be measured, from a conversion result provided from the input frequency domain conversion step and a conversion result provided from the response frequency domain conversion step.

The present invention is a computer-readable medium having a program of instructions for execution by a computer to perform a measuring process, the measuring process including: a response signal measuring step that measures a response signal within a time domain, the response signal being acquired by applying a pulse having a width of not less than one femtosecond nor more than 1000 femtoseconds to an object to be measured; an input frequency domain conversion step that converts the pulse into a frequency domain; a response frequency domain conversion step that converts a measurement result from the response signal measuring step into a frequency domain; and a frequency characteristic acquisition step that acquires a frequency characteristic of the object to be measured, from a conversion result provided from the input frequency domain conversion step and a conversion result provided from the response frequency domain conversion step.

### BRIEF DESCRIPTION OF DRAWINGS

FIG. 1 is a diagram illustrating a configuration of a measuring apparatus 1 according to a first embodiment of the present invention;

FIG. 2 is a diagram illustrating a configuration of the probe body 10 according to the first embodiment;

FIG. 3 is a functional block diagram illustrating a configuration of the signal processing device 20 according to the first embodiment;

FIG. 4 is a diagram illustrating a configuration of the probe body 10 according to the second embodiment;

FIG. 5 is a diagram illustrating a configuration of the measuring apparatus 1 according to the third embodiment;

FIG. 6 is a diagram illustrating a configuration of the vector network analyzer 30 according to the third embodiment;

FIG. 7 is a functional block diagram illustrating a configuration of the signal processing device 20 according to the fourth embodiment;

FIG. 8 is a diagram illustrating a response signal according to the fourth embodiment (FIG. 8(a)) and pulses generated by the pulse signal source 14 (FIG. 8(b));

FIG. 9 is a diagram illustrating a method of measuring the time difference Δt0 between a pulse and a response signal according to a fourth embodiment; and

FIG. 10 is a diagram illustrating a timing of starting the measurement of the response signal within the time domain according to the fourth embodiment.

### DESCRIPTION OF EMBODIMENTS

Some embodiments of the present invention will be described below with reference to the accompanying drawings.

### First Embodiment

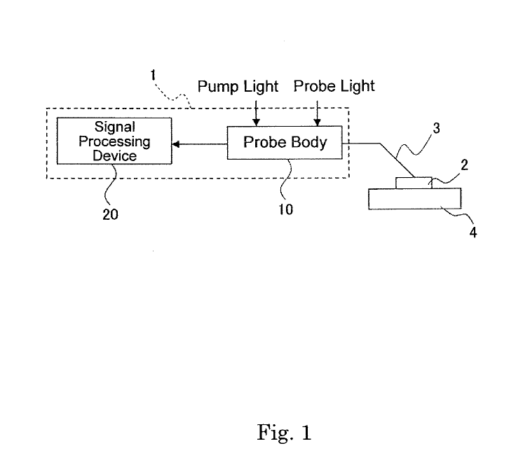

FIG. 1 is a diagram illustrating a configuration of a measuring apparatus 1 according to a first embodiment of the present invention.

The measuring apparatus 1 according to the first embodiment of the present invention includes a probe body 10 and a signal processing device 20. The measuring apparatus 1 is used to measure an object to be measured 2.

A probe tip 3 is attached to the probe body 10. The probe tip 3 is in contact with the object to be measured 2 mounted on a substrate 4. The object to be measured 2 may be, for example, a wire on the substrate 4. If the substrate 4 is a multilayer substrate, a wire in the multilayer substrate may be the object to be measured 2.

The probe body 10 receives pump light and probe light. The probe body 10 is connected to the signal processing device 20.

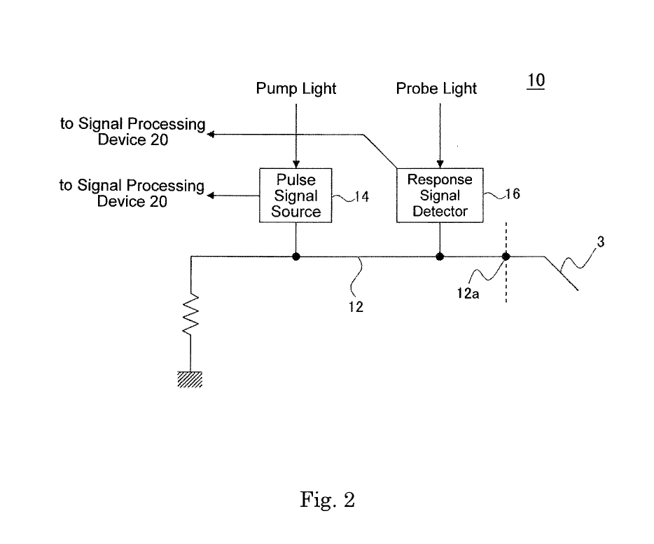

FIG. 2 is a diagram illustrating a configuration of the probe body 10 according to the first embodiment. The probe body 10 in the first embodiment includes a transmission line 12, a pulse signal source 14, and a response signal detector 16.

The pulse signal source 14 generates pulses. The response signal detector 16 detects a response signal (a signal obtained by giving the pulse generated by the pulse signal source 14 to the object to be measured 2). Each of the pulse signal source 14 and the response signal detector 16 is, for example, a photoconductive antenna. The pulse generated by the pulse signal source 14 and the detection result from the response signal detector 16 are transmitted to the signal processing device 20.

The pump light (e.g., a laser pulse having a wavelength of 1550 nm and a pulse width of 1 to 1000 femtoseconds) is given to the pulse signal source 14. In response to this, the pulse signal source 14 outputs a pulse having a width of not less than one femtosecond nor more than 1000 femtoseconds.

The probe light (e.g., a laser pulse having a wavelength of 1550 nm and a pulse width of 1 to 1000 femtoseconds) is given to the response signal detector 16. Then, the response signal detector 16 detects an intensity of a response signal at the time when the probe light is given to the response signal detector 16. On the basis of this detection result, the response signal can be measured by a known pump-probe method.

For example, suppose the pump light has pulses with a repetition interval T. In this case, the probe light also has pulses with the repetition interval T, and a length of the optical path of the probe light is varied, whereby the response signals can be measured. Alternatively, by shifting each repetition interval of the probe light from T by a small amount of time (smaller than the pulse width of the response signal), the response signals can be measured. This small amount of time may be either constant or variable.

Both the pulse signal source 14 and the response signal detector 16 are connected directly to the transmission line 12. The pulses and the response signals are transmitted over the transmission line 12. The transmission line 12 has one end 12a connected to the probe tip 3. The transmission line 12 has the other end grounded through a resistor. No bias voltage is applied to the transmission line 12.

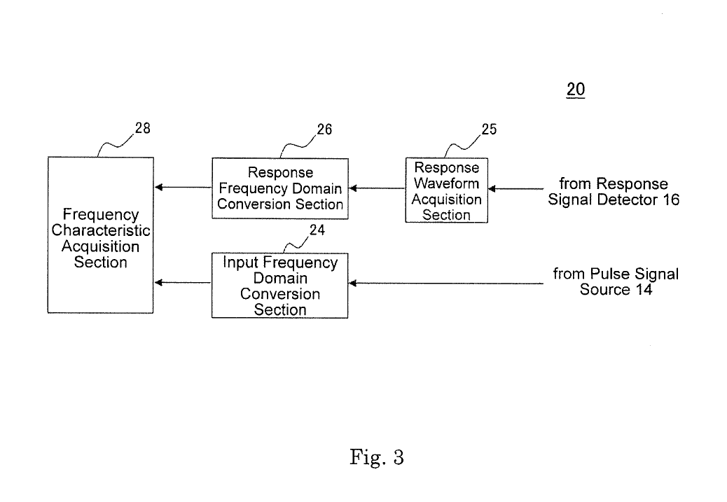

FIG. 3 is a functional block diagram illustrating a configuration of the signal processing device 20 according to the first embodiment. The signal processing device 20 in the first embodiment includes an input frequency domain conversion section 24, a response waveform acquisition section (response signal measuring section) 25, a response frequency domain conversion section 26, and a frequency characteristic acquisition section 28.

The input frequency domain conversion section 24 receives a pulse from the pulse signal source 14 and converts the pulse into a frequency domain (e.g., converts the pulse into a frequency domain by means of an FFT).

The response waveform acquisition section (response signal measuring section) 25 uses a known pump-probe method as described above to measure a response signal within the time domain on the basis of a detection result from the response signal detector 16. The detection result from the response signal detector 16 is simply a measurement of the response signal which is obtained at the time when the response signal detector 16 receives the probe light. The response waveform acquisition section 25 interpolates the detection result from the response signal detector 16, thereby enabling the acquisition of the waveform of the response signal, namely, enabling the measurement of the response signal within the time domain.

The response frequency domain conversion section 26 converts the measurement result from the response waveform acquisition section 25 into a frequency domain (e.g., converts the measurement result into a frequency domain by means of an FFT).

The frequency characteristic acquisition section 28 acquires frequency characteristics of the object to be measured 2 based on the conversion result from the input frequency domain conversion section 24 and the conversion result from the response frequency domain conversion section 26.

Next, an operation in the first embodiment will be described.

First, pump light (femtosecond laser pulses) is given to the pulse signal source 14. In response, the pulse signal source 14 outputs pulses, each of which has a width of not less than one femtosecond nor more than 1000 femtoseconds. The pulses output from the pulse signal source 14 are given to the object to be measured 2 through the transmission line 12 and the probe tip 3.

The pulses are reflected by the object to be measured 2 to become a response signal, which is then given to the response signal detector 16 through the probe tip 3 and the transmission line 12. The response signal detector 16 detects intensities of the response signals at the time of receiving probe light (femtosecond laser pulses).

Since the pump light has pulses that are repeatedly output, the pulse signal source 14 also repeatedly outputs pulses. Therefore, the response signals are repeatedly given to the response signal detector 16 as well. The response signal detector 16 detects the response signals that have been repeatedly given, at the time when the response signal detector 16 receives the probe light (that is pulses repeatedly output).

The response waveform acquisition section 25 uses a known pump-probe method as described above to measure the response signals within the time domain on the basis of the detection result from the response signal detector 16.

The input frequency domain conversion section 24 receives pulses from the pulse signal source 14 and converts the pulses into a frequency domain (e.g., converts the pulses into a frequency domain by means of an FFT). The response frequency domain conversion section 26 converts the measurement result from the response waveform acquisition section 25 into a frequency domain (e.g., converts the measurement result into a frequency domain by means of an FFT). The frequency characteristic acquisition section 28 acquires frequency characteristics of the object to be measured 2 from the conversion result made from the input frequency domain conversion section 24 and the conversion result made from the response frequency domain conversion section 26.

The first embodiment can facilitate the measurement of the frequency characteristics of the object to be measured 2 over a wide frequency band.

That is, a pulse having a width of not less than one femtosecond nor more than 1000 femtoseconds, which is output from the pulse signal source 14, covers a wide frequency band. Thus, the response signal acquired from the object to be measured 2 reflects the frequency characteristics of the object to be measured 2 over the wide frequency band. In short, by measuring the response signal, the frequency characteristics of the object to be measured 2 can be measured over the wide frequency band.

When using waveguides in the related art, many types of waveguides must be used and replaced one after another. However, the first embodiment can eliminate the need to replace waveguides, thus facilitating the measurement.

### Second Embodiment

The measuring apparatus 1 according to a second embodiment differs from the first embodiment in that the pulse signal source 14 and the response signal detector 16 are electromagnetically coupled to the transmission line 12.

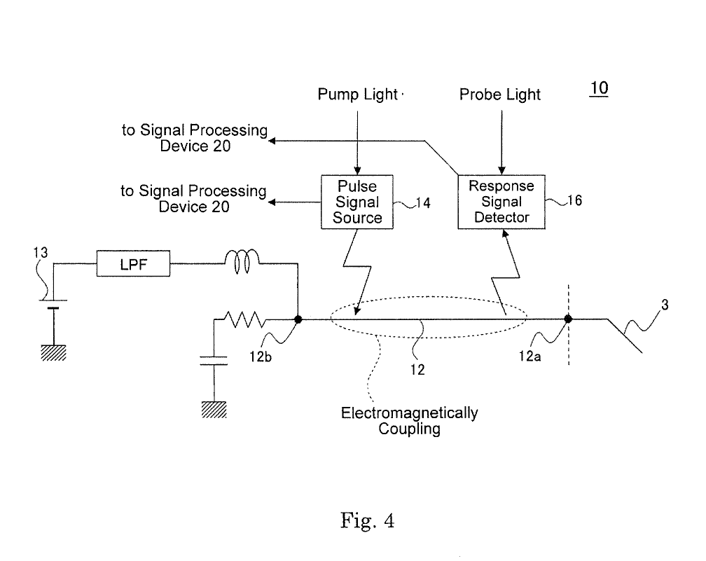

FIG. 4 is a diagram illustrating a configuration of the probe body 10 according to the second embodiment. The probe body 10 in the second embodiment includes the transmission line 12, a bias power source 13, the pulse signal source 14, and the response signal detector 16. Hereinafter, components that are the same as those in the first embodiment are given identical numbers and will not be described.

The pulse signal source 14 and the response signal detector 16, which are the same as in the first embodiment, will not be described. However, the pulse signal source 14 and the response signal detector 16 are electromagnetically coupled to the transmission line 12.

The transmission line 12 has the other end 12b connected to the bias power source 13 through an LPF (low-pass filter) and an inductance. The bias voltage is thereby applied to the transmission line 12. The bias power source 13 is a DC voltage source.

The other end 12b of the transmission line 12 is grounded through a resistor and a capacitance.

The signal processing device 20 in the measuring apparatus 1 according to the second embodiment, which is the same as in the first embodiment, will not be described.

Next, an operation of the second embodiment will be described.

First, pump light (femtosecond laser pulses) is given to the pulse signal source 14. In response, the pulse signal source 14 outputs pulses, each of which has a width of not less than one femtosecond nor more than 1000 femtoseconds. The pulses output from the pulse signal source 14 are given to the probe tip 3 through the transmission line 12 electromagnetically coupled to the pulse signal source 14, and further given to the object to be measured 2.

The pulses are reflected by the object to be measured 2 to become response signals, which then are fed, through the probe tip 3 and the transmission line 12, to the response signal detector 16 that is electromagnetically coupled to the transmission line 12. The response signal detector 16 detects intensities of the response signals at the time when the response signal detector 16 receives the probe light (femtosecond laser pulse).

Note that since the pump light has pulses that are repeatedly output, the pulse signal source 14 also repeatedly outputs pulses. Therefore, the response signals are repeatedly given to the response signal detector 16 as well. The response signal detector 16 detects the response signals that have been repeatedly given, at the time when the response signal detector 16 receives the probe light (that is pulses repeatedly output).

An operation of the signal processing device 20, which is the same as that in the first embodiment, will not be described.

The second embodiment produces the same effects as those in the first embodiment.

### Third Embodiment

The measuring apparatus 1 according to a third embodiment differs from the measuring apparatus 1 according to the first and second embodiments in including a vector network analyzer 30. The probe body 10 in the measuring apparatus 1 according to the third embodiment may be the probe body embodied in either the first embodiment (see FIG. 2) or the second embodiment (see FIG. 4).

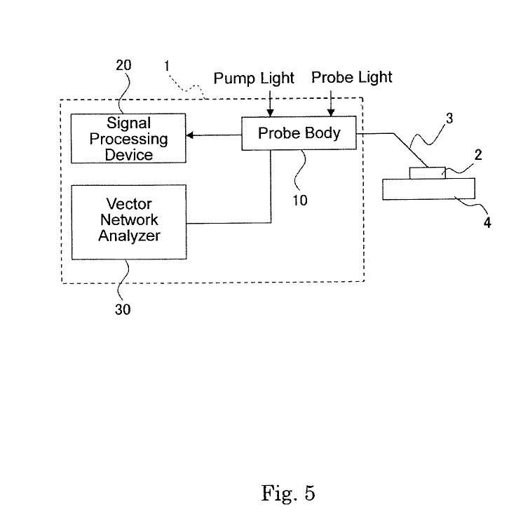

FIG. 5 is a diagram illustrating a configuration of the measuring apparatus 1 according to the third embodiment. The measuring apparatus 1 in the third embodiment includes the probe body 10, the signal processing device 20, and the vector network analyzer 30. The probe body 10 and the signal processing device 20, which are the same as in the first and second embodiments, will not be described. The vector network analyzer 30, is connected to the transmission line 12 of the probe body 10.

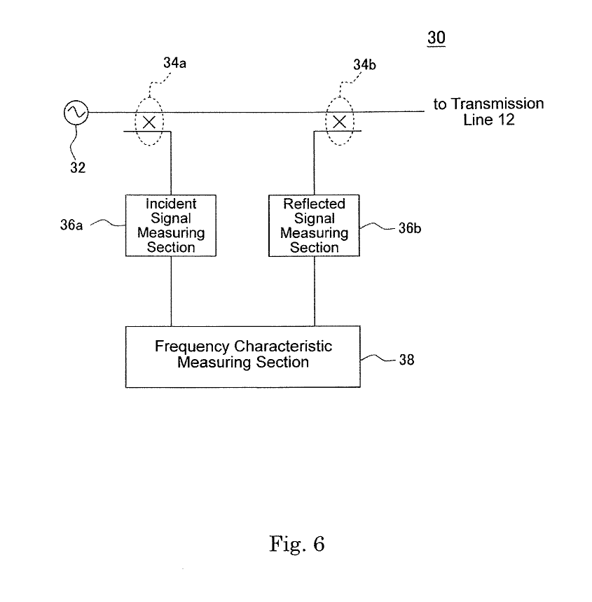

FIG. 6 is a diagram illustrating a configuration of the vector network analyzer 30 according to the third embodiment. The vector network analyzer 30 includes an incident signal source 32, bridges 34a and 34b, an incident signal measuring section 36a, a reflected signal measuring section (acquired signal measuring section) 36b, and a frequency characteristic measuring section 38.

The incident signal source 32 allows a weak low-frequency signal in a pulse generated by the pulse signal source 14 to enter the object to be measured 2 through the transmission line 12 of the probe body 10. Although the pulse generated by the pulse signal source 14 covers a wide frequency band, the low-frequency component is weaker than the high-frequency component (e.g., terahertz component). The incident signal source 32 outputs this low-frequency component and allows the low-frequency component to enter the object to be measured 2. The incident signal source 32 has a variable frequency in the low frequency band.

The bridge 34a gives the signal output from the incident signal source 32 to the incident signal measuring section 36a. The incident signal measuring section 36a measures (the S parameters of) an incident signal that is allowed to enter the object to be measured 2 from the incident signal source 32.

The bridge 34b gives an acquired signal to the reflected signal measuring section (acquired signal measuring section) 36b; the acquired signal is obtained by allowing the incident signal to enter the object to be measured 2 (e.g., a signal based on a pulse reflected by the object to be measured 2). The reflected signal measuring section (acquired signal measuring section) 36b measures (the S parameters of) the acquired signal.

The frequency characteristic measuring section 38 measures frequency characteristics of the object to be measured 2 from the measurement results from the incident signal measuring section 36a and the reflected signal measuring section 36b.

Next, an operation of the third embodiment will be described.

The operations of the probe body 10 and the signal processing device 20, which are the same as those in the first embodiment, will not be described.

The incident signal source 32 in the vector network analyzer 30 allows a low-frequency signal to enter the object to be measured 2. In this case, pulses generated by the pulse signal source 14 each contain a weak low-frequency component.

The incident signal measuring section 36a receives an incident signal from the bridge 34a and measures (the S parameters of) the incident signal. The reflected signal measuring section 36b receives an acquired signal (reflected signal) from the bridge 34b and measures (the S parameters of) the acquired signal. The frequency characteristic measuring section 38 measures the frequency characteristics of the object to be measured 2 from the measurement results from the incident signal measuring section 36a and the reflected signal measuring section 36b.

The third embodiment produces the same effects as those in the first embodiment.

The first embodiment and second embodiment are disadvantageous in that weak low-frequency components in pulses generated by the pulse signal source 14 may make it difficult to measure frequency characteristics of the object to be measured 2 in a low frequency band.

The third embodiment, however, can overcome the disadvantage of the first embodiment and the second embodiment, since the incident signal source 32 outputs and gives a low-frequency component to the object to be measured 2, thereby allowing the vector network analyzer 30 to measure the frequency characteristics of the object to be measured 2 in a low frequency band.

### Fourth Embodiment

The measuring apparatus 1 according to a fourth embodiment differs from the measuring apparatus 1 according to the first and second embodiments in that the signal processing device 20 includes a time difference measuring section 22. The probe body 10 in the measuring apparatus 1 according to the fourth embodiment may be either the probe body 10 described in the first embodiment (see FIG. 2) or the probe body 10 described in the second embodiment (see FIG. 4).

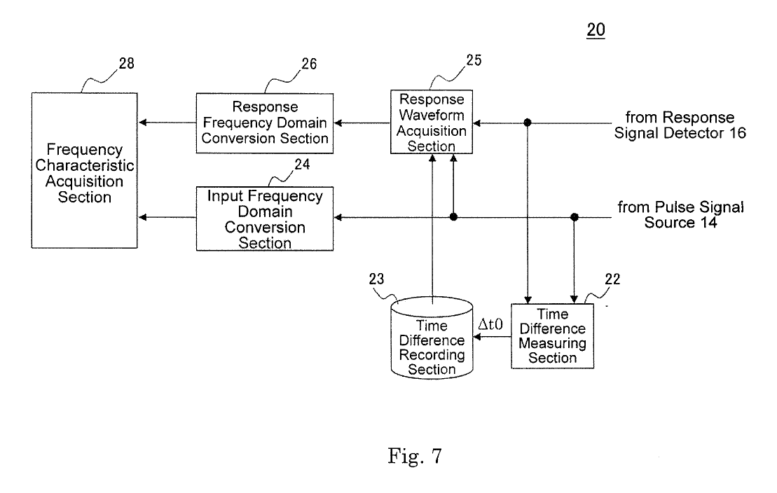

FIG. 7 is a functional block diagram illustrating a configuration of the signal processing device 20 according to the fourth embodiment. The signal processing device 20 according to the fourth embodiment includes the time difference measuring section 22, a time difference recording section 23, the input frequency domain conversion section 24, the response waveform acquisition section (response signal measuring section) 25, the response frequency domain conversion section 26, and the frequency characteristic acquisition section 28. Hereinafter, components that are the same as those in the first embodiment are given identical numbers and will not be described.

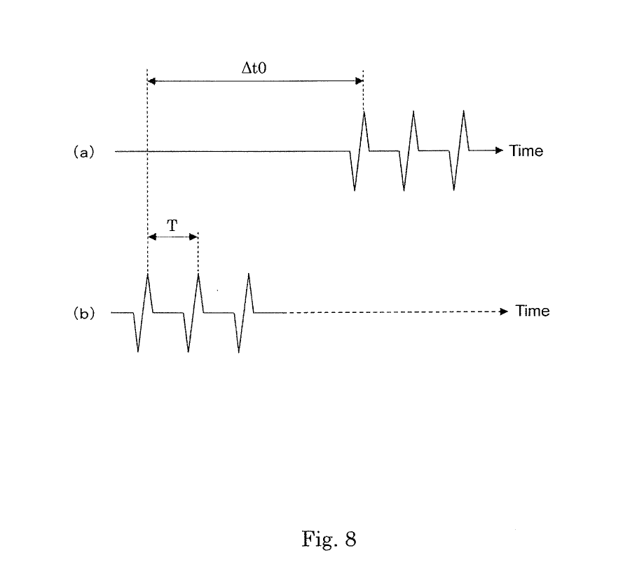

The time difference measuring section 22 measures a time difference Δt0 (see FIG. 8 to FIG. 10) between a pulse generated by the pulse signal source 14 and the response signal. The time difference recording section 23 records the time difference Δt0.

The input frequency domain conversion section 24, the response waveform acquisition section 25, the response frequency domain conversion section 26, and the frequency characteristic acquisition section 28, which are the same as in the first embodiment, will not be described.

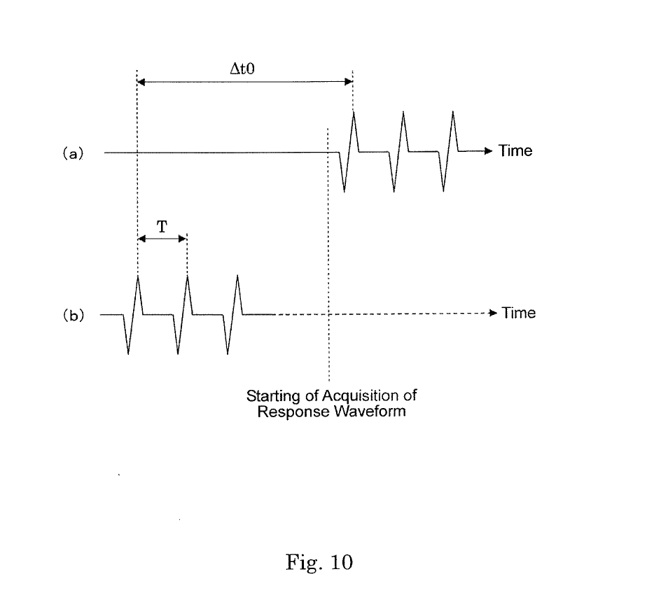

The response waveform acquisition section (response signal measuring section) 25 reads the time difference Δt0 from the time difference recording section 23, and receives an occurrence of a pulse in the pulse signal source 14. After only a time based on the time difference Δt0 (e.g., a time slightly shorter than Δt0: see FIG. 10) has passed since this instant (the occurrence of the pulse in the pulse signal source 14), the response waveform acquisition section 25 measures a response signal within the time domain.

Next, an operation of the fourth embodiment will be described.

FIG. 8 is a diagram illustrating a response signal according to the fourth embodiment (FIG. 8(a)) and pulses generated by the pulse signal source 14 (FIG. 8(b)).

A time difference Δt0 has passed after a pulse has been generated by the pulse signal source 14 and before a response signal reaches the response signal detector 16. This time difference Δt0 is much longer than a repetition interval T of the pulses and the response signal. Therefore, if the response waveform acquisition section 25 starts measuring a response signal within the time domain simultaneously with the generation of a pulse in the pulse signal source 14, a measurement result acquired over the time difference Δt0, or over a long time, may be in vain.

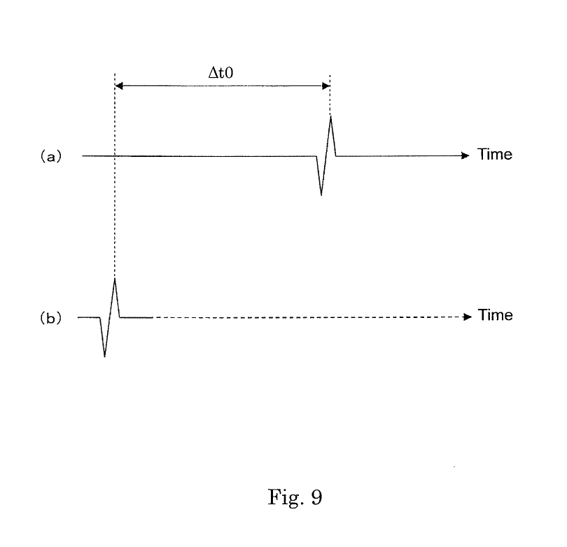

FIG. 9 is a diagram illustrating a method of measuring the time difference Δt0 between a pulse and a response signal according to a fourth embodiment.

First, the pulse signal source 14 generates a single pulse (see FIG. 9(b)). Then, the response signal detector 16 detects a response signal (see FIG. 9(a)). The time difference measuring section 22 acquires the instant of generation of the pulse, from the pulse signal source 14, as well as the instant of detection of the response signal, from the response signal detector 16. Then, the time difference measuring section 22 measures a time difference Δt0 between the pulse and the response signal. The measured time difference Δt0 is recorded in the time difference recording section 23.

FIG. 10 is a diagram illustrating a timing of starting the measurement of the response signal within the time domain according to the fourth embodiment.

Then, the pulse signal source 14 repeatedly generates pulses (see FIG. 10(b)). The response waveform acquisition section (response signal measuring section) 25 receives an occurrence of a pulse in the pulse signal source 14. After a time (see FIG. 10(a)) that is slightly shorter than the time difference Δt0 has passed since this instance (the occurrence of the pulse in the pulse signal source 14), the response waveform acquisition section 25 measures a response signal within the time domain. The response waveform acquisition section 25 reads the time difference Δt0 from the time difference recording section 23 and will use the time difference Δt0. The subsequent operation, which is the same as in the first embodiment, will not be described.

According to the fourth embodiment, the response waveform acquisition section 25 can start measuring a response signal within the time domain immediately before the response signal detector 16 detects the response signal. This can prevent the measurement from being made uselessly over substantially the time difference Δt0.

In the fourth embodiment, the response waveform acquisition section (response signal measuring section) 25 reads the time difference Δt0 from the time difference recording section 23. However, a response signal can also be measured, in the following manner, within the time domain after only a time based on the time difference Δt0 has passed since generation of a pulse in the pulse signal source 14.

As an example, a probe light source (not illustrated) that generates probe light may read the time difference Δt0 from the time difference recording section 23. Then, the probe light source may generate probe light after a time that is slightly shorter than the time difference Δt0 has passed since generation of the pulse in the pulse signal source 14.

Alternatively, the response signal detector 16 may read the time difference Δt0 from the time difference recording section 23. Then, the response signal detector 16 may start detecting a response signal after a time that is slightly shorter than the time difference Δt0 has passed since generation of the pulse in the pulse signal source 14.

The above method also makes it possible to measure a response signal within the time domain after a time based on the time difference Δt0 has passed since generation of a pulse in the pulse signal source 14.

The foregoing embodiments can be implemented in the following manner. A computer that includes a CPU, a hard disk, and a medium (a floppy [registered trademark] disk, a CD-ROM, etc.) readout device may read a program that implements the above components, such as the signal processing device 20, and which is stored in a medium, and then may install the program onto the hard disk. This method can also achieve the above function.

1. A measuring apparatus, comprising:
a processor; and
a memory including a program that, when executed by the processor, causes the processor to perform operations including:
measuring a response signal within a time domain, the response signal being acquired by applying a pulse having a width of not less than one femtosecond and not more than 1000 femtoseconds to an object to be measured;
converting the pulse into a frequency domain;
converting a measurement result from the measuring of the response signal into a frequency domain; and
acquiring a frequency characteristic of the object to be measured, from a conversion result provided from the converting of the pulse into the frequency domain and a conversion result provided from the converting of the measurement result into the frequency domain.

2. The measuring apparatus according to claim 1, further comprising:
a probe tip that makes contact with the object to be measured;
a transmission line connected to the probe tip, the transmission line being adapted to transmit the pulse and the response signal therethrough;
a pulse signal source that generates the pulse; and
a response signal detector that detects the response signal, wherein
the processor measures the response signal within the time domain based on a detection result from the response signal detector.

3. The measuring apparatus according to claim 2, wherein
no bias voltage is applied to the transmission line, and
the transmission line is connected directly to both the pulse signal source and the response signal detector.

4. The measuring apparatus according to claim 2, wherein
a bias voltage is applied to the transmission line, and
the transmission line is electromagnetically coupled to both the pulse signal source and the response signal detector.

5. The measuring apparatus according to claim 1, further comprising:
an incident signal source that allows a weak, low-frequency signal in the pulse to enter the object to be measured, wherein
the operations further include:
measuring an incident signal entered by the incident signal source;
measuring an acquired signal obtained by allowing the incident signal to enter the object to be measured; and
measuring a frequency characteristic of the object to be measured, from measurement results provided from the measuring of the incident signal and the measuring of the acquired signal.

6. The measuring apparatus according to claim 1, the operations further including:
measuring a time difference between the pulse and the response signal, wherein
the processor measures the response signal within the time domain after a time based on the time difference has passed since generation of the pulse.

7. A measuring method, comprising:
measuring a response signal within a time domain, the response signal being acquired by applying a pulse having a width of not less than one femtosecond and not more than 1000 femtoseconds to an object to be measured;
converting the pulse into a frequency domain;
converting a measurement result from the measuring of the response signal into a frequency domain; and
acquiring a frequency characteristic of the object to be measured, from a conversion result provided from the converting of the pulse into the frequency domain and a conversion result provided from the converting of the measurement result into the frequency domain.

8. A non-transitory computer-readable medium including a program of instructions for execution by a computer to perform a measuring process, the measuring process comprising:
measuring a response signal within a time domain, the response signal being acquired by applying a pulse having a width of not less than one femtosecond and not more than 1000 femtoseconds to an object to be measured;
converting the pulse into a frequency domain;
converting a measurement result from the measuring of the response signal into a frequency domain; and
acquiring a frequency characteristic of the object to be measured, from a conversion result provided from the converting of the pulse into the frequency domain and a conversion result provided from the converting of the measurement result into the frequency domain.
